(19) United States
(12) Patent Application Publication
(10) Pub. No.: US 2026/0047290 A1
(43) Pub. Date: Feb. 12, 2026

(54) DISPLAY PANEL, ELECTRONIC APPARATUS, AND METHOD FOR MANUFACTURING THE ELECTRONIC APPARATUS

(71) Applicant: SAMSUNG DISPLAY CO., LTD., YONGIN-SI (KR)

(72) Inventor: CHOLONG WON, Yongin-si (KR)

(21) Appl. No.: 19/296,055

(22) Filed: Aug. 11, 2025

(30) Foreign Application Priority Data
Aug. 12, 2024 (KR) 10-2024-0107494

(51) Int. Cl. H10K 59/131; H01L 25/18; H10K 59/12; H10K 59/95

(52) U.S. Cl. CPC H10K 59/131; H01L 25/18; H10K 59/1201; H10K 59/95

(57) ABSTRACT

A display panel includes a pixel. A signal line is electrically connected to the pixel. A signal pad is connected to the signal line. The signal pad includes a first conductive layer electrically connected to a portion of the signal line. A second conductive layer is disposed on the first conductive layer. An insulating layer is disposed between the first conductive layer and the second conductive layer. An opening is defined in the second conductive layer. The opening exposes a portion of a top surface of the insulating layer.

### CROSS-REFERENCE TO RELATED APPLICATIONS

This application claims priority under 35 U.S.C. § 119 to Korean Patent Application No. 10-2024-0107494, filed on Aug. 12, 2024 in the Korean Intellectual Property Office, the disclosure of which is incorporated by reference in its entirety herein.

### 1. TECHNICAL FIELD

The present disclosure herein relates to a display panel, an electronic apparatus, and a method for manufacturing the electronic apparatus, and more particularly, to a display panel including a pad area, an electronic apparatus, and a method for manufacturing the electronic apparatus.

### 2. DISCUSSION OF RELATED ART

Various electronic apparatuses include at least one display area that is activated in response to electrical signals. The electronic apparatuses may detect inputs applied from the outside through the display area, and also display various images in the display area to provide information for users.

An electronic apparatus includes a display panel and a circuit board. The display panel may be connected to a main board through the circuit board. A driving chip may be mounted on the display panel.

### SUMMARY

The present disclosure provides a display panel with increased bonding reliability, and an electronic apparatus including the display panel.

The present disclosure also provides a method for manufacturing an electronic apparatus with increased processibility.

According to an embodiment of the present inventive concept, a display panel includes a pixel. A signal line is electrically connected to the pixel. A signal pad is connected to the signal line. The signal pad includes a first conductive layer electrically connected to a portion of the signal line. A second conductive layer is disposed on the first conductive layer. An insulating layer is disposed between the first conductive layer and the second conductive layer. An opening is defined in the second conductive layer. The opening exposes a portion of a top surface of the insulating layer.

In an embodiment, the insulating layer may include elastomer.

In an embodiment, a modulus of the insulating layer may be in a range of about 2 GPa to about 10 GPa.

In an embodiment, on a plane, the insulating layer may be disposed inside of the first conductive layer and inside the second conductive layer.

In an embodiment, on a plane, the first conductive layer and the second conductive layer may overlap each other. The insulating layer is not disposed on the portion of the first conductive layer and the insulating layer exposes the portion of the first conductive layer.

In an embodiment, a side surface of the insulating layer may be covered by the second conductive layer.

In an embodiment, a bottom surface of the insulating layer may be covered by the first conductive layer.

In an embodiment, the portion of the signal line may be disposed below the first conductive layer, and the display panel may further include a pad insulating layer disposed between the portion of the signal line and the first conductive layer in a thickness direction of the signal pad.

In an embodiment, the display panel may further include a base layer disposed below the portion of the signal line.

In an embodiment, a contact hole is defined in the pad insulating layer. The contact hole exposes the portion of the signal line. The first conductive layer may be electrically connected to the portion of the signal line through the contact hole.

In an embodiment, the contact hole and the insulating layer may be disposed to be spaced apart from each other on a plane.

In an embodiment, the opening may include a plurality of openings.

In an embodiment, each of the first conductive layer and the second conductive layer may have a three-layer structure of titanium/aluminum/titanium.

According to an embodiment of the present inventive concept, an electronic apparatus includes a display module comprising a display panel having a display area that includes a pixel, and a pad area including a signal pad connected to the pixel through a signal line, and an input sensor disposed on the display panel. An electronic component comprises a bump electrode that is disposed in the pad area. An adhesive layer is disposed between the display panel and the electronic component. The signal pad comprises a first conductive layer electrically connected to a portion of the signal line. A second conductive layer is disposed on the first conductive layer. An insulating layer is disposed between the first conductive layer and the second conductive layer. An opening is defined in the second conductive layer. The opening exposes a portion of a top surface of the insulating layer. The second conductive layer is in direct contact with, and is electrically connected to, the bump electrode.

In an embodiment, on a plane, the insulating layer may be disposed inside the first conductive layer and inside the second conductive layer, and a side surface of the insulating layer may be covered by the second conductive layer.

In an embodiment, the insulating layer may include elastomer, and each of the first conductive layer and the second conductive layer may have a three-layer structure of titanium/aluminum/titanium.

In an embodiment, the opening may include a plurality of openings.

According to an embodiment of the present inventive concept, a method for manufacturing an electronic apparatus includes preparing a preliminary display panel including a preliminary signal pad including a first conductive layer, an insulating layer disposed on the first conductive layer, and a preliminary second conductive layer disposed on the insulating layer. A display panel is formed by patterning the preliminary second conductive layer to expose a portion of a top surface of the insulating layer to form a second conductive layer. The display panel and an electronic component including a bump electrode are bonded to each other through an adhesive layer. The bonding of the electronic component includes bonding the second conductive layer and the bump electrode to be in direct contact with, and electrically connected to, each other.

In an embodiment, on a plane, the insulating layer may be disposed inside the first conductive layer and inside the second conductive layer, and a side surface of the insulating layer may be covered by the second conductive layer.

In an embodiment, the insulating layer may include elastomer, and each of the first conductive layer and the second conductive layer may have a three-layer structure of titanium/aluminum/titanium.

### BRIEF DESCRIPTION OF THE DRAWINGS

The accompanying drawings are included to provide a further understanding of the present inventive concept, and are incorporated in and constitute a part of this specification. The drawings illustrate embodiments of the present inventive concept and, together with the description, serve to explain principles of the present inventive concept. In the drawings:

FIG. 1 is an assembled perspective view of a display device according to an embodiment of the present inventive concept;

FIGS. 2A and 2B are each an exploded perspective view of a display device according to embodiments of the present inventive concept;

FIG. 3 is a cross-sectional view of a display module according to an embodiment of the present inventive concept;

FIG. 4 is a plan view of a display panel according to an embodiment of the present inventive concept;

FIG. 5 is a cross-sectional view of a display panel illustrating a pixel according to an embodiment of the present inventive concept;

FIG. 6 is an enlarged exploded perspective view of a pad area of a display device according to an embodiment of the present inventive concept;

FIG. 7 is an enlarged plan view of a pad area according to an embodiment of the present inventive concept;

FIGS. 8A to 8C are each a cross-sectional view of a portion of a pad area according to embodiments of the present inventive concept;

FIG. 9 is a cross-sectional view illustrating a bonding structure of a display device according to an embodiment of the present inventive concept;

FIG. 10 is a flowchart of a method for manufacturing a display device according to an embodiment of the present inventive concept; and

FIGS. 11 to 16 are each a cross-sectional view illustrating one step of a method for manufacturing a display device according to embodiments of the present inventive concept.

### DETAILED DESCRIPTION OF EMBODIMENTS

In the present disclosure, it will be understood that when an element (or region, layer, section, etc.) is referred to as being “on”, “connected to” or “coupled to” another element, it can be disposed directly on, connected or coupled to the other element or a third element may be disposed between the elements. When an element is referred to as being “directly on”, “directly connected to” or “directly coupled to” another element, no intervening elements may be present.

Like reference numbers or symbols refer to like elements throughout. In addition, in the drawings, the thickness, the ratio, and the dimension of elements may be exaggerated for effective description of the technical contents. The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present invention, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present inventive concept will be described with reference to the accompanying drawings.

The present inventive concept concerns a display panel that includes a signal pad having an insulating layer disposed directly between first and second conductive layers. The second conductive layer includes an opening that exposes a portion of a top surface of the insulating layer. The insulating layer may be disposed as one body on one signal pad without being patterned. Therefore, the insulating layer may have a degree of material freedom in which the insulating layer may be composed of various different materials. Additionally, a contact area between the insulating layer and the first conductive layer may have increased bonding force.

The insulating layer may include an elastomer providing a restoring force to the signal pad to increase bonding reliability. The second conductive layer may be patterned to provide a high degree of freedom for micro-patterning and to increase bond reliability with a bump electrode.

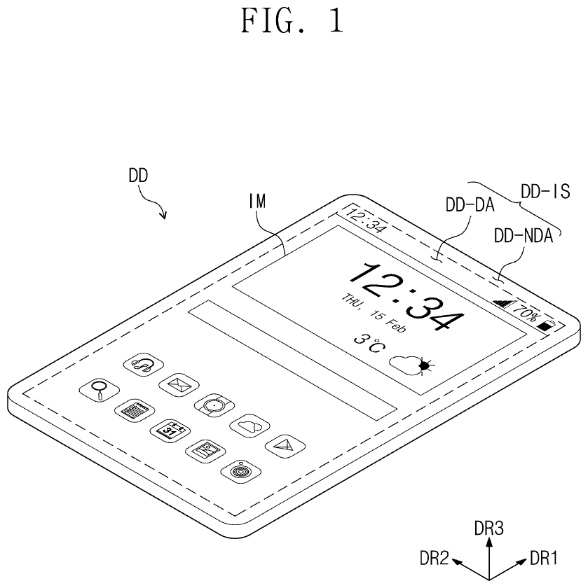

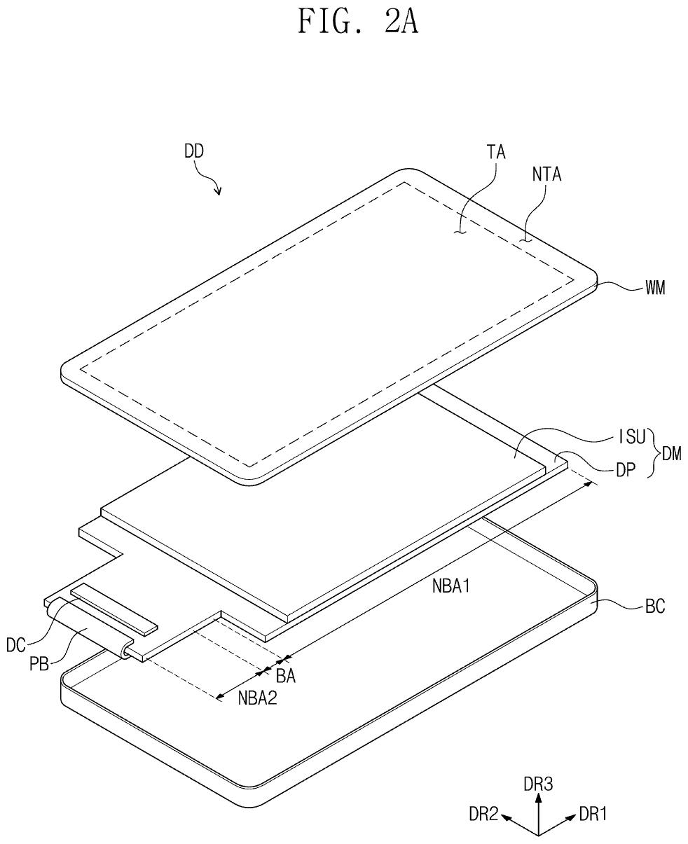

FIG. 1 is a perspective view of a display device DD according to an embodiment of the present inventive concept. FIGS. 2A and 2B are each an exploded perspective view of the display device DD according to an embodiment of the present inventive concept. As an example, FIG. 2B illustrates the display device DD in a state in which a bending area BA illustrated in FIG. 2A is bent. In the present disclosure, the display device DD may be referred to as an electronic apparatus.

Referring to FIG. 1, a mobile phone terminal is illustrated as an example of the display device DD. The display device DD according to an embodiment of the present inventive concept may be applied to a large-sized electronic apparatus such as television or monitor, and also to a small- and medium-sized electronic apparatuses such as tablet computer, vehicle navigation unit, game console, or smart watch. However, embodiments of the present inventive concept are not necessarily limited thereto and the electronic device that the display device DD may be applied to may be various different small-sized, medium-sized or large-sized electronic devices.

In an embodiment, the display device DD may have a rectangular shape having long sides extending in a first direction DR1 and having short sides extending in a second direction DR2 crossing the first direction DR1 on a plane. However, an embodiment of the present inventive concept is not necessarily limited thereto, and the display device DD may have various shapes such as circle and polygon on a plane.

Hereinafter, a direction substantially perpendicularly crossing a plane defined by the first direction DR1 and the second direction DR2 is defined as a third direction DR3. The state being “when viewed on a plane” used herein may mean a state being when viewed in the third direction DR3.

The display device DD may be rigid or flexible. The term “flexible” refers to a characteristic of being capable of bending, and may include all from a fully folded structure to a structure capable of bending at the level of several nanometers. For example, the flexible display device DD may include a curved display device, a rollable display device, and a foldable display device.

The display device DD may display an image IM through a display surface DD-IS. Software application icons and a clock, temperature and calendar window are illustrated as an example of the image IM in FIG. 1. The display surface DD-IS may be parallel to a plane defined by the first direction DR1 and the second direction DR2.

The display surface DD-IS may include a display area DD-DA which displays the image IM, and a non-display area DD-NDA adjacent to the display area DD-DA (e.g., in the first and/or second directions DR1, DR2). The non-display area DD-NDA may be an area which does not display the image IM. However, an embodiment of the present inventive concept is not necessarily limited thereto, and the non-display area DD-NDA may be adjacent to one side of the display area DD-DA or be omitted.

Referring to FIGS. 2A and 2B, the display device DD may include a window WM, a display module DM, and an accommodation member BC.

The window WM may be disposed above the display module DM, and transmit an image provided from the display module DM to the outside. In an embodiment, the window WM may include a base layer and functional layers disposed on the base layer. In an embodiment, the functional layers may include a protective layer, an anti-fingerprint layer, and the like. The base layer of the window WM may be made of glass, sapphire, plastic, or the like. The base layer of the window WM may include an optically transparent insulating material. For example, the base layer of the window WM may include a glass or plastic film, or include a glass substrate and a plastic film coupled to each other through an adhesive.

The window WM may include a transmission area TA and a non-transmission area NTA. In an embodiment, the transmission area TA may overlap the display area DD-DA illustrated in FIG. 1, and have a shape corresponding to the display area DD-DA. The non-transmission area NTA may overlap the non-display area DD-NDA illustrated in FIG. 1, and have a shape corresponding to the non-display area DD-NDA. The non-transmission area NTA may be an area having a relatively low light transmittance compared to the transmission area TA. The non-transmission area NTA may be defined in a partial area of the base layer of the window WM by a bezel pattern, and an area in which the bezel pattern is not disposed may be defined as the transmission area TA. However, embodiments of the present inventive concept are not necessarily limited thereto, and the non-transmission area NTA may be omitted in some embodiments.

In an embodiment, an anti-reflective layer may be disposed between the window WM and the display module DM (e.g., in the third direction DR3). The anti-reflective layer may reduce reflectance of external light incident from the outside of the display device DD. The anti-reflective layer may include color filters. The color filters may have an arrangement. For example, the color filters may be arranged considering emissive colors of pixels included in a display panel DP to be described later. In addition, the anti-reflective layer may further include a black matrix adjacent to the color filters.

According to an embodiment of the present inventive concept, the display module DM may include the display panel DP and an input sensor ISU.

In an embodiment, the display panel DP may be one of a liquid crystal display panel, an electrophoretic display panel, a microelectromechanical system (MEMS) display panel, an electrowetting display panel, an organic light emitting display panel, an inorganic light emitting display panel, and a quantum dot light emitting display panel. However, embodiments of the present inventive concept are not necessarily limited thereto. Hereinafter, the display panel DP is described as the organic light emitting display panel for convenience of explanation.

In an embodiment, the input sensor ISU may include any one of capacitance sensor, an optical sensor, an ultrasonic sensor, and an electromagnetic induction sensor. The input sensor ISU may be formed on the display panel DP through a continuous process, or may be separately manufactured and then attached to an upper side of the display panel DP through an adhesive layer, and the input sensor ISU is not necessarily limited to any one embodiment.

The display device DD may further include a driving chip DC disposed on the display panel DP. The display device DD may further include a circuit board PB disposed on the display panel DP. In this embodiment, the circuit board PB may be a flexible circuit board. However, embodiments of the present inventive concept are not necessarily limited thereto. For example, the circuit board PB may be rigid. The circuit board PB may electrically connect the display panel DP and a main circuit board to each other.

The driving chip DC may include driving elements, for example, a data driving circuit, for driving pixels of the display panel DP. FIG. 2A illustrates a structure in which the driving chip DC is mounted on the display panel DP. However, embodiments of the present inventive concept are not necessarily limited thereto. For example, the driving chip DC may be mounted on the circuit board PB. In this embodiment, the driving chip DC and the circuit board PB which are directly mounted on the display panel DP may be collectively referred to as an electronic component.

In an embodiment, the display panel DP may include the bending area BA, and a first non-bending area NBA1 and a second non-bending area NBA2 which are arranged to be spaced apart from each other in the first direction DR1 with the bending area BA therebetween.

The bending area BA may be defined as an area in which the display panel DP is bent along a virtual bending axis BX extending in the second direction DR2. The first non-bending area NBA1 may be defined as an area overlapping the transmission area TA, and the second non-bending area NBA2 may be defined as an area to which the circuit board PB is connected. When the bending area BA is bent around the bending axis BX, the circuit board PB and the driving chip DC may be bent in a direction towards a rear surface of the display panel DP and disposed below the rear surface of the display panel DP. In an embodiment, additional components for compensating for a height difference between the circuit board PB and the rear surface of the display panel DP, which is generated due to the bending area BA, may be disposed.

According to an embodiment, a width of the first non-bending area NBA1 in the second direction DR2 may be greater than a width of each of the bending area BA and the second non-bending area NBA2 in the second direction DR2. However, embodiments of the present inventive concept are not necessarily limited thereto. For example, the width of the bending area BA in the second direction DR2 may be provided in a shape, in which the width gradually decreases from the first non-bending area NBA1 towards the second non-bending area NBA2, and is not necessarily limited to any one embodiment.

As illustrated in FIG. 2B, as a portion of the display panel DP is bent, the circuit board PB electrically bonded to the display panel DP may be disposed on the rear surface of the display panel DP.

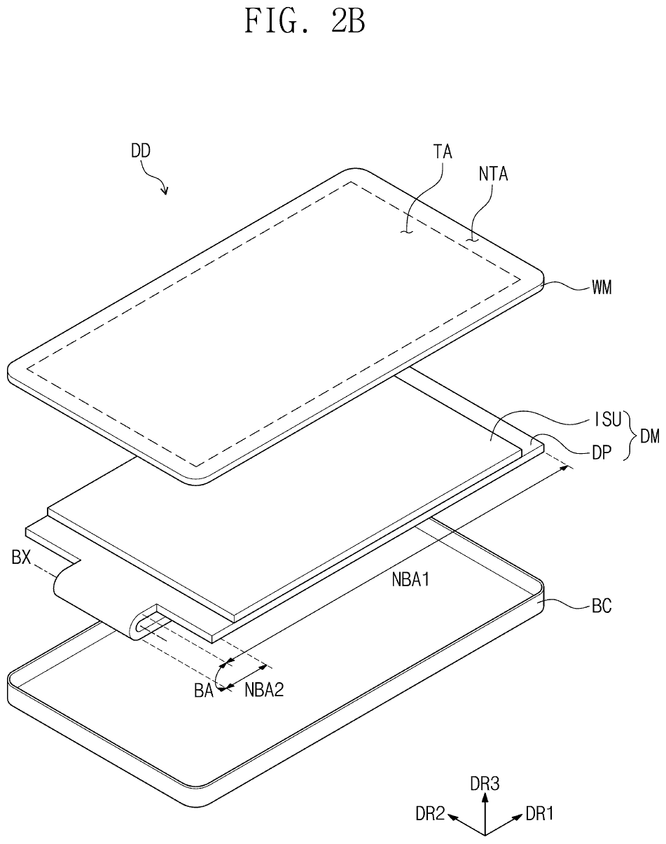

The accommodation member BC may accommodate the display module DM and be coupled to the window WM. The circuit board PB may be disposed on one end of the display panel DP and be electrically connected to a circuit element layer DP-CL to be described with reference to FIG. 3. In an embodiment, the display device DD may further include a main board, and electronic modules, a camera module, a power module, and the like which are mounted on the main board.

Although the mobile phone terminal is described above as an example of the display device DD, the display device DD may be various other electronic device that include two or more bonded electronic components. The display panel DP and the driving chip DC mounted on the display panel DP may correspond to different electronic components from each other, and only these components may constitute the display device DD. The display panel DP and the circuit board PB connected to the display panel DP may also correspond to different electronic components from each other, and only these components may constitute the display device DD. Alternatively, only the display panel DP, the main board, and the electronic module mounted on the main board may constitute the display device DD. Hereinafter, the display device DD according to an embodiment of the present inventive concept will be described mainly in terms of a bonding structure of the display panel DP and the driving chip DC mounted on the display panel DP.

FIG. 3 is a cross-sectional view of a display module DM according to an embodiment of the present inventive concept.

Referring to FIG. 3, in an embodiment a display panel DP may include a base layer BL, a circuit element layer DP-CL, a display element layer DP-OLED, and an upper insulating layer TFL. An input sensor ISU may be disposed on (e.g., disposed directly thereon) the upper insulating layer TFL.

The display panel DP may include a display area DP-DA and a non-display area DP-NDA. The display area DP-DA of the display panel DP may correspond to the display area DD-DA illustrated in FIG. 1 or the transmission area TA illustrated in FIG. 2A, and the non-display area DP-NDA may correspond to the non-display area DD-NDA illustrated in FIG. 1 or the non-transmission area NTA illustrated in FIG. 2A.

In an embodiment, the base layer BL may be a flexible substrate and include a plastic substrate, a glass substrate, a metal substrate, an organic/inorganic composite material substrate, or the like.

The circuit element layer DP-CL may include at least one intermediate insulating layer and a circuit element. The intermediate insulating layer may include at least one intermediate inorganic layer and at least one intermediate organic layer. In an embodiment, the circuit element may include signal lines, a driving circuit of a pixel, and the like. The insulating layer, a semiconductor layer, and a conductive layer are formed through a process such as coating or deposition. Thereafter, the insulating layer, the semiconductor layer, and the conductive layer may be selectively patterned through a photolithography process and an etching process. A semiconductor pattern, a conductive pattern, the signal lines, and the like are formed through those processes. The patterns disposed at the same layer are formed through the same process. Hereinafter, when patterns are formed through the same process, it means that the patterns include the same material and has the same stacked structure.

The display element layer DP-OLED may include a plurality of light emitting elements. The display element layer DP-OLED may further include an organic layer such as a pixel defining film.

The upper insulating layer TFL may seal the display element layer DP-OLED. The upper insulating layer TFL may be disposed on (e.g., disposed directly thereon) the display element layer DP-OLED. The upper insulating layer TFL may overlap the display area DP-DA and the non-display area DP-NDA. The upper insulating layer TFL may overlap at least a portion of the non-display area DP-NDA. As an example, the upper insulating layer TFL may include a thin-film encapsulation layer. The thin-film encapsulation layer may include a stacked structure of inorganic layer/organic layer/inorganic layer. The upper insulating layer TFL may protect the display element layer DP-OLED from moisture, oxygen, and foreign matter such as dust particles. However, embodiments of the present inventive concept are not necessarily limited thereto, and the upper insulating layer TFL may further include an additional insulating layer in addition to the thin-film encapsulation layer. For example, an optical insulating layer for controlling a refractive index may be further included.

In an embodiment of the present inventive concept, an encapsulation substrate may be provided instead of the upper insulating layer TFL. In this embodiment, the encapsulation substrate may oppose the base layer BL (e.g., in the third direction DR3), and the circuit element layer DP-CL and the display element layer DP-OLED may be disposed between the encapsulation substrate and the base layer BL (e.g., in the third direction DR3).

In an embodiment, the input sensor ISU may be directly disposed on the display panel DP. In the present disclosure, when “a component A is directly disposed on a component B”, it means that a separate layer is not disposed between the components A and B. In this embodiment, the input sensor ISU may be manufactured through a continuous process together with the display panel DP. However, embodiments of the present inventive concept are not necessarily limited thereto, and the input sensor ISU may be provided as a separate panel and be coupled to the display panel DP through an adhesive layer. Alternatively, as an example, the input sensor ISU may be omitted.

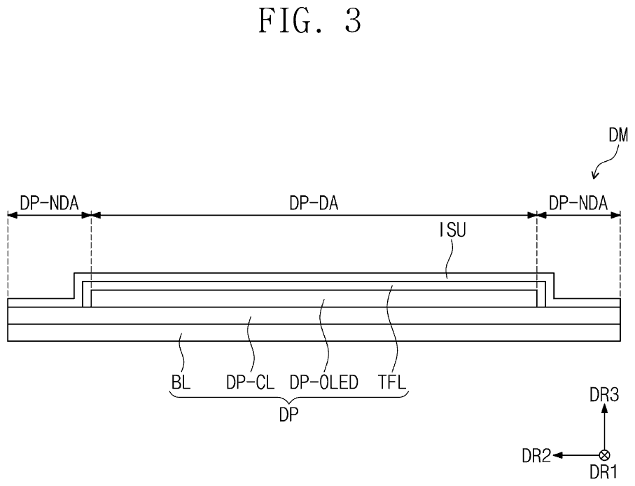

FIG. 4 is a plan view of a display panel DP according to an embodiment of the present inventive concept.

Referring to FIG. 4, in an embodiment the display panel DP may include a plurality of pixels PX, a gate driving circuit GDC, a plurality of signal lines SGL, and a plurality of signal pads DP-PD.

The pixels PX may be disposed in a display area DP-DA. Each of the pixels PX includes a light emitting element and a pixel driving circuit connected to thereto. In an embodiment, the light emitting element may be an organic light emitting element. The gate driving circuit GDC sequentially outputs gate signals to a plurality of gate lines GL to be described later. In an embodiment, a transistor of the gate driving circuit GDC may be formed through the same process as a transistor of the pixel PX, for example, a low temperature polycrystalline silicon (LTPS) process or a low temperature polycrystalline oxide (LTPO) process. The display panel DP may further include another driving circuit that provides the pixels PX with an emission control signal.

In an embodiment, the signal lines SGL may include the gate lines GL, data lines DL, a power line PL, and a control signal line CSL. Each of the gate lines GL may be connected to (e.g., electrically connected thereto) a corresponding pixel PX of the pixels PX, and each of the data lines DL may be connected to (e.g., electrically connected thereto) a corresponding pixel PX of the pixels PX. The power line PL may be connected to (e.g., electrically connected thereto) the pixels PX. The control signal line CSL may provide the gate driving circuit GDC with the control signals.

The signal lines SGL may overlap the display area DP-DA and a non-display area DP-NDA. In an embodiment, each of the signal lines SGL may include a line portion LP. In an embodiment, each of the signal lines SGL may further include a pad portion. The line portion LP may overlap the display area DP-DA and the non-display area DP-NDA. The pad portion is connected to an end of the line portion LP.

In an embodiment, the plurality of signal pads DP-PD may include first pads PD1, second pads PD2, and third pads PD3. An area in which the first and second pads PD1 and PD2 are disposed may be defined as a first pad area PA1, and an area in which the third pads PD3 are disposed may be defined as a second pad area PA2.

The first pad area PA1 may be an area overlapping a driving chip DC, and the second pad area PA2 may be an area overlapping a circuit board PB. In an embodiment, the first pad area PA1 may include a first area B1 in which the first pads PD1 are disposed, and a second area B2 in which the second pads PD2 are disposed. The first pad area PA1 and the second pad area PA2 may be disposed within the non-display area DP-NDA. The first pad area PA1 and the second pad area PA2 may be spaced apart from each other in the first direction DR1. The first area B1, the second area B2 and the second pad area PA2 in which one pad row is disposed are illustrated as an example in FIG. 4. However, embodiments of the present inventive concept are not necessarily limited thereto, and a plurality of pad rows may be disposed in the first area B1, the second area B2 and the second pad area PA2.

Each of the first pads PD1 may be connected to a corresponding data line DL of the data lines DL. In an embodiment, the first pads PD1 and the second pads PD2 may be electrically connected to each other. The second pads PD2 may be connected to the third pads PD3 through connection signal lines SCLn.

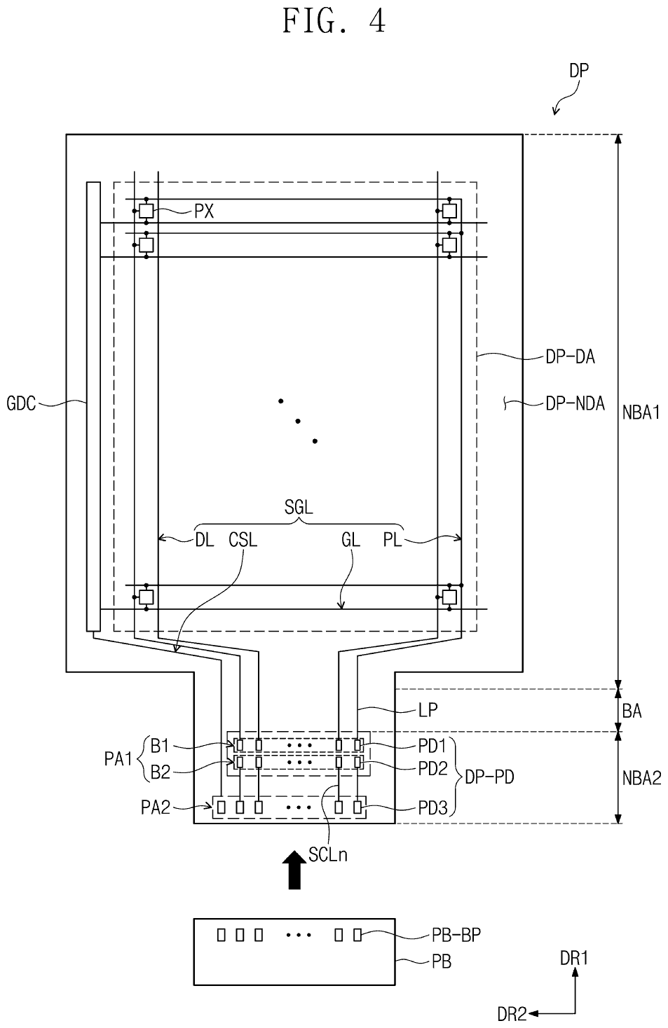

FIG. 5 is a cross-sectional view of a display panel DP, which illustrates a pixel PX according to an embodiment of the present inventive concept.

Referring to FIG. 5, in an embodiment a display area DP-DA may include an emission area PXA and a non-emission area NPXA. Each of pixels may include a light emitting element OLED and a pixel driving circuit connected to the light emitting element OLED. In an embodiment, the pixel PX may include a transistor TR and the light emitting element OLED.

As an example, FIG. 5 illustrates one transistor TR. However, embodiments of the present inventive concept are not necessarily limited thereto. The pixel PX according to an embodiment may include seven transistors and at least one capacitor, and the seven transistors and the capacitor may be electrically connected to each other. However, the number of each of the transistor and the capacitor that constitute the pixel PX may vary and is not necessarily limited to any one embodiment.

In an embodiment, the display panel DP may include a plurality of insulating layers, a semiconductor pattern, a conductive pattern, a signal line, and the like. The insulating layers, a semiconductor layer, and a conductive layer may be formed through a process such as coating or deposition. Thereafter, the insulating layers, the semiconductor layer, and the conductive layer may be selectively patterned through a photolithography process. The semiconductor pattern, the conductive pattern, and the signal line, and the like, which are included in a circuit element layer DP-CL and a display element layer DP-OLED, may be formed through those processes.

In an embodiment, a base layer BL may include a synthetic resin film. The base layer BL may have a multilayer structure. For example, in an embodiment the base layer BL may have a three-layer structure of a synthetic resin layer, an inorganic layer and a synthetic resin layer. In an embodiment, the synthetic resin layer may be a polyimide-based resin layer, however the material thereof is not necessarily limited thereto. In addition, the base layer BL may include a glass substrate, a metal substrate, an organic/inorganic composite material substrate, or the like.

In an embodiment, the circuit element layer DP-CL may include a barrier layer BRL, a buffer layer BFL, first to sixth insulating layers 10 to 60, the transistor TR, a connection signal line SCLd, an upper electrode UE, a first connection electrode CNE1, and a second connection electrode CNE2. At least one inorganic layer is disposed on a top surface of the base layer BL.

At least one inorganic layer is disposed on a top surface of the base layer BL. The inorganic layer may be provided in a multilayer structure. The barrier layer BRL may be disposed on the base layer BL (e.g., disposed directly thereon in the third direction DR3). The buffer layer BFL may be disposed on the barrier layer BRL (e.g., disposed directly thereon in the third direction DR3). The barrier layer BFL and the buffer layer BRL may each be an inorganic layer.

The semiconductor pattern is disposed on the buffer layer BFL. The semiconductor pattern may include polysilicon. However, embodiments of the present inventive concept are not necessarily limited thereto, and the semiconductor pattern may include amorphous silicon or a metal oxide.

FIG. 5 only illustrates a portion of the semiconductor pattern, and the semiconductor pattern may be further disposed in another area of the pixel PX on a plane. The semiconductor pattern may be arranged over the plurality of pixels according to a specific rule. The semiconductor pattern has different electrical properties according to whether or not the semiconductor pattern is doped. The semiconductor pattern may include a first region and a second region. The first region may be doped with an n-type dopant or a p-type dopant. A p-type transistor includes a doped region doped with the p-type dopant.

The first region may have higher conductivity than the second region, and substantially serve as an electrode or a signal line. The second region may be a region that has a low doping concentration or is not doped, and may substantially correspond to an active (e.g., a channel) region of a transistor. For example, one portion of the semiconductor pattern may be an active region of the transistor, another portion thereof may be a source or a drain of the transistor, and still another portion thereof may be a connection electrode or a connection signal line.

As illustrated in FIG. 5, a source S, an active region A, and a drain D of the transistor TR may be provided from the semiconductor pattern.

FIG. 5 illustrates a portion of the connection signal line SCLd provided from the semiconductor pattern. In an embodiment, the connection signal line SCLd may be electrically connected to a drain of one of the transistors in the pixel PX.

The first insulating layer 10 is disposed on the buffer layer BFL (e.g., disposed directly thereon in the third direction DR3). The first insulating layer 10 may cover the semiconductor pattern. The first insulating layer 10 may overlap, in common, the plurality of pixels. A gate G may be disposed on the first insulating layer 10 (e.g., disposed directly thereon in the third direction DR3). The gate G may be a portion of a metal pattern. The gate G may overlap the active region A (e.g., in the third direction DR3). The gate G may function as a mask in a process of doping the semiconductor pattern.

The second insulating layer 20 which covers the gate G may be disposed on the first insulating layer 10 (e.g., disposed directly thereon in the third direction DR3). The second insulating layer 20 may overlap, in common, the plurality of pixels. The upper electrode UE may be disposed on the second insulating layer 20 (e.g., disposed directly thereon in the third direction DR3). The upper electrode UE may overlap the gate G of the transistor TR (e.g., in the third direction DR3). The upper electrode UE may be a portion of a metal pattern. A portion of the gate G and the upper electrode UE overlapping the portion may define a capacitor.

The third insulating layer 30 which covers the upper electrode UE may be disposed on the second insulating layer 20 (e.g., disposed directly thereon in the third direction DR3). In an embodiment, the first connection electrode CNE1 disposed on the third insulating layer 30 may be connected to the connection signal line SCLd through a contact hole CNT-1 passing through the first to third insulating layers 10 to 30.

The fourth insulating layer 40 which covers the first connection electrode CNE1 may be disposed on the third insulating layer 30 (e.g., disposed directly thereon in the third direction DR3). The first to fourth insulating layers 10 to 40 may each be an inorganic layer and/or an organic layer, and have a single-layer or multilayer structure.

The first connection electrode CNE1 may be disposed on the fourth insulating layer 40 (e.g., disposed directly thereon in the third direction DR3) and covered by the fifth insulating layer 50. Alternatively, an embodiment may include both a first connection electrode disposed on the third insulating layer 30 and covered by the fourth insulating layer 40, and a first connection electrode disposed on the fourth insulating layer 40 and covered by the fifth insulating layer 50.

The fifth insulating layer 50 may be disposed on the fourth insulating layer 40 (e.g., disposed directly thereon in the third direction DR3). The fifth insulating layer 50 may be an organic layer. The second connection electrode CNE2 may be disposed on the fifth insulating layer 50 (e.g., disposed directly thereon in the third direction DR3). In an embodiment, the second connection electrode CNE2 may be connected to the first connection electrode CNE1 through a contact hole CNT-2 passing through the fourth insulating layer 40 and the fifth insulating layer 50.

The sixth insulating layer 60 which covers the second connection electrode CNE2 may be disposed on the fifth insulating layer 50 (e.g., disposed directly thereon in the third direction DR3). The sixth insulating layer 60 may be an organic layer. A first electrode AE may be disposed on the sixth insulating layer 60 (e.g., disposed directly thereon in the third direction DR3). The first electrode AE may be connected to the second connection electrode CNE2 through a contact hole CNT-3 passing through the sixth insulating layer 60.

The circuit element layer DP-CL may include a plurality of connection electrodes connected to the transistors, and some of the plurality of connection electrodes may be disposed on different layers from each other. In an embodiment, the first connection electrode CNE1 may extend to be connected to the transistor TR. However, embodiments of the present inventive concept are not necessarily limited thereto and positions of the plurality of connection electrodes may vary.

The display element layer DP-OLED may include a pixel defining film PDL and the light emitting element OLED. A pixel opening portion OPN may be defined in the pixel defining film PDL. The pixel opening portion OPN of the pixel defining film PDL may expose at least a portion of the first electrode AE. In an embodiment, the emission area PXA may be defined to correspond to a partial area of the first electrode AE, which is exposed by the pixel opening portion OPN.

A hole control layer HCL may be disposed, in common, in the emission area PXA and the non-emission area NPXA. In an embodiment, the hole control layer HCL may include a hole transport layer and/or a hole injection layer. An emission layer EML may be disposed on the hole control layer HCL. The emission layer EML may be disposed in an area corresponding to the pixel opening portion OPN. For example, the emission layer EML may be separately provided in each of pixels. However, embodiments of the present inventive concept are not necessarily limited thereto, and the emission layer EML may be provided, in common, in the plurality of pixels by using an open mask.

An electron control layer ECL may be disposed on the emission layer EML. The electron control layer ECL may include an electron transport layer and/or an electron injection layer. The hole control layer HCL and the electron control layer ECL may be provided, in common, in the plurality of pixels by using an open mask. A second electrode CE may be disposed on the electron control layer ECL. The second electrode CE may have a one-body shape and be disposed, in common, in the plurality of pixels. An upper insulating layer TFL may be disposed on the second electrode CE. The upper insulating layer TFL may include a plurality of thin films.

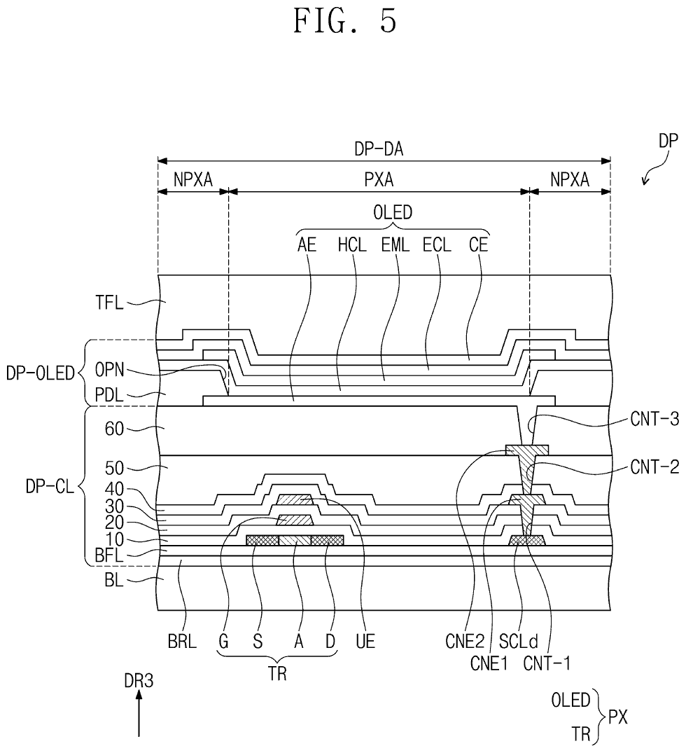

FIG. 6 is an enlarged exploded perspective view of pad areas PA1 and PA2 of a display device DD according to an embodiment of the present inventive concept. As an example, FIG. 6 illustrates a driving chip DC and a circuit board PB that are separated from a display panel DP. First pads PD1, second pads PD2, connection signal lines SCLn, and third pads PD3 in FIG. 6 are the same as/similar to the first pads PD1, the second pads PD2, the connection signal lines SCLn, and the third pads PD3 in FIG. 4, respectively, and thus will not be described or will be briefly described.

Referring to FIGS. 4 and 6, in an embodiment the driving chip DC may be bonded to a first pad area PA1 through a first adhesive layer CF1. The circuit board PB may be bonded to a second pad area PA2 through a second adhesive layer CF2. In an embodiment, the first and second adhesive layers CF1 and CF2 may each include a synthetic resin having an adhesive property. The first and second adhesive layers CF1 and CF2 may each be a non-conductive film. For example, each of the first and second adhesive layers CF1 and CF2 may not include a conductive ball but include only the synthetic resin having an adhesive property.

In an embodiment, the driving chip DC may include a driving integrated circuit D-IC and chip bump electrodes DC-BP mounted in the driving chip DC. The driving integrated circuit D-IC may include a top surface DC-US and a bottom surface DC-DS opposite to each other in the third direction DR3, and the bottom surface DC-DS may be a surface facing the first and second pads PD1 and PD2. The chip bump electrodes DC-BP may be disposed on the bottom surface DC-DS of the driving integrated circuit D-IC.

In an embodiment, the chip bump electrodes DC-BP may include first bumps BP1 electrically connected to the first pads PD1, respectively, and second bumps BP2 electrically connected to the second pads PD2, respectively. The first bumps BP1 may be arranged along the second direction DR2, and the second bumps BP2 may be spaced apart from the first bumps BP1 in the first direction DR1 and arranged along the second direction DR2.

In an embodiment, the driving chip DC may receive first signals from the outside through the second pads PD2 and the second bumps BP2. The driving chip DC may provide second signals, which are generated based on the first signals, to the first pads PD1 through the first bumps BP1. For example, the driving chip DC may include a data driving circuit. The first signals may be image signals that are digital signals applied from the outside, and the second signals may be data signals that are analog signals. In an embodiment, the driving chip DC may generate analog voltages corresponding to grayscale values of the image signals. The data signals may be provided to the pixel PX through the data line DL illustrated in FIG. 4.

In an embodiment, each of the first bumps BP1 and the second bumps BP2 may have a shape which protrudes from the bottom surface DC-DS of the driving integrated circuit D-IC and is exposed to the outside. In an embodiment, when the first adhesive layer CF1 is cured, the first pads PD1 and the first bumps BP1 may be fixed in a contact state with each other, and the second pads PD2 and the second bumps BP2 may be fixed in a contact state with each other.

In an embodiment, the circuit board PB may include a base layer P-BS and board bump electrodes PB-BP mounted in the circuit board PB. The circuit board PB may include a top surface PB-US and a bottom surface PB-DS, and the bottom surface PB-DS may be a surface facing the third pads PD3. The board bump electrodes PB-BP may be disposed on the bottom surface PB-DS of the base layer P-BS. The board bump electrodes PB-BP may be electrically connected to the third pads PD3, respectively. The board bump electrodes PB-BP may be arranged along the second direction DR2. The circuit board PB may provide the driving chip DC with image signals, driving voltages, and other control signals.

In an embodiment, the board bump electrodes PB-BP may have a shape which protrudes from the bottom surface PB-DS of the base layer P-BS and is exposed to the outside. In an embodiment, when the second adhesive layer CF2 is cured, the third pads PD3 and the board bump electrodes PB-BP may be fixed in a contact state with each other.

An electronic component may include a substrate and a bump electrode disposed below the substrate. In an embodiment in which the electronic component corresponds to the driving chip DC, the substrate may correspond to the driving integrated circuit D-IC of the driving chip DC, and the bump electrode may correspond to the chip bump electrode DC-BP. Alternatively, in an embodiment in which the electronic component corresponds to the circuit board PB, the substrate may correspond to the base layer P-BS of the circuit board PB, and the bump electrode may correspond to the board bump electrode PB-BP.

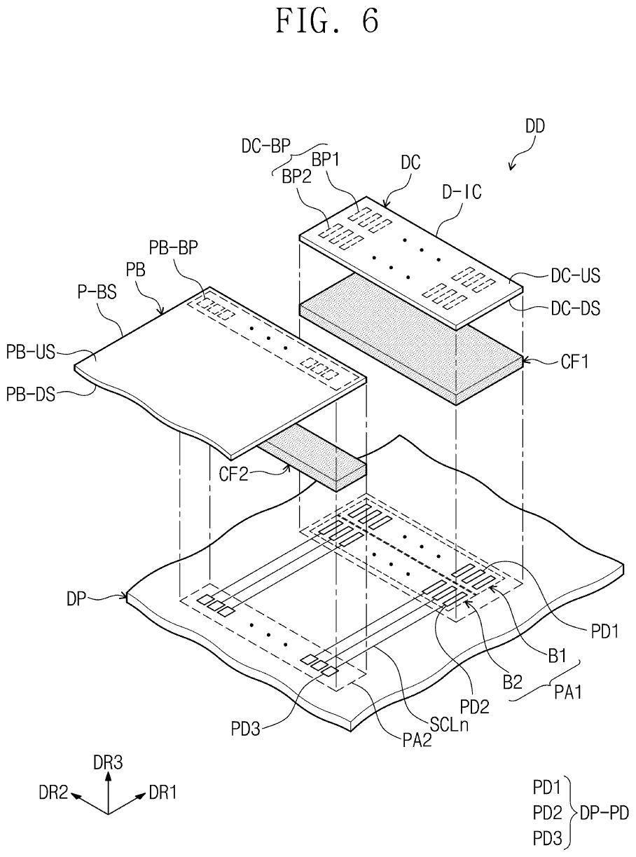

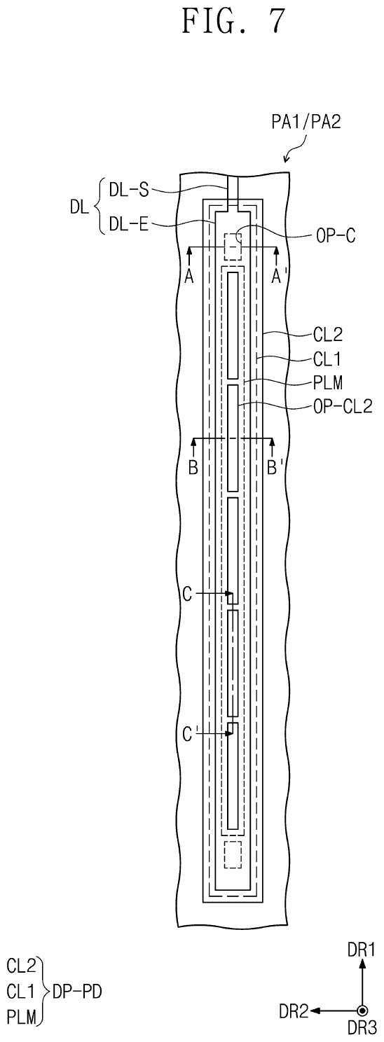

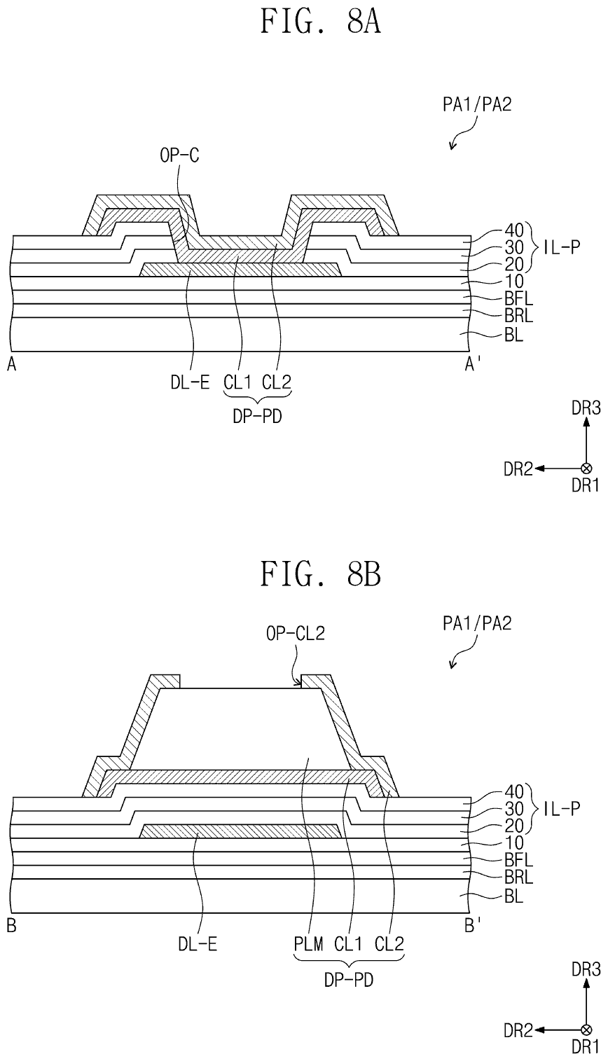

FIG. 7 is an enlarged plan view of pad areas PA1 and PA2 according to an embodiment of the present inventive concept. FIGS. 8A to 8C are each a cross-sectional view of a portion of each of the pad areas PA1 and PA2 according to an embodiment of the present inventive concept. FIG. 9 is a cross-sectional view illustrating a bonding structure of the display device DD (see FIG. 6) according to an embodiment of the present inventive concept. FIG. 8A is a cross-sectional view of the pad areas PA1 and PA2 corresponding to line A-A′ in FIG. 7. FIG. 8B is a cross-sectional view of the pad areas PA1 and PA2 corresponding to line B-B′ in FIG. 7. FIG. 8C is a cross-sectional view of the pad areas PA1 and PA2 corresponding to line C-C′ in FIG. 7. FIG. 9 is a cross-sectional view of the display device DD (see FIG. 6) corresponding to line C-C′ in FIG. 7.

A signal pad DP-PD illustrated in FIGS. 7 to 9 may be one of the first to third pads PD1 to PD3 described with reference to FIGS. 4 and 6. FIG. 7 illustrates, as an example of a signal line, a data line DL including an end portion DL-E and a line portion DL-S which have different widths from each other. However, embodiments of the present inventive concept are not necessarily limited thereto. Here, the width may indicate a length or width of the end portion DL-E or the line portion DL-S in the second direction DR2, which may be perpendicular to the direction that the data line DL extends longitudinally. In an embodiment, the signal line may be a different type of signal line other than the data line DL, and may have a uniform width regardless of the end portion DL-E and the line portion DL-S. The end portion DL-E may correspond to the pad portion described with reference to FIG. 4. The end portion DL-E may be referred to as a portion of the data line DL or a signal line.

Hereinafter, the pad areas PA1 and PA2 will be described mainly in terms of a first pad area PA1 in which the data line DL is disposed for economy of explanation. However, the same content about the first pad area PA1 may apply to a second pad area PA2 except that, in the second pad area PA2, the connection signal line SCLn (see FIG. 4) is disposed instead of the data line DL.

Referring to FIG. 7, the signal pad DP-PD includes a first conductive layer CL1, a second conductive layer CL2, and an insulating layer PLM disposed in an inner side of the first conductive layer CL1 and the second conductive layer CL2.

The end portion DL-E of the data line DL may have a shape extending longitudinally in the first direction DR1 on a plane. For example, in the end portion DL-E, a length or width in the first direction DR1 may be greater than a length or width in the second direction DR2. The end portion DL-E may overlap the first conductive layer CL1 on a plane.

The first conductive layer CL1 may be disposed to overlap the end portion DL-E of the data line DL (e.g., in the third direction DR3). FIG. 7 illustrates the end portion DL-E which is disposed in the inner side of the first conductive layer CL1 (e.g., in a plan view). However, embodiments of the present inventive concept are not necessarily limited thereto. In an embodiment, the first conductive layer CL1 may be connected to the end portion DL-E of the data line DL through at least one contact hole OP-C. Therefore, the first conductive layer CL1 may be electrically connected to the signal line, such as the data line DL. In other words, the signal pad DP-PD may be connected to the signal line. The contact hole OP-C may be defined in a pad insulating layer IL-P (see FIG. 8A). As an example, FIG. 7 illustrates two contact holes OP-C. However, the number of the contact holes OP-C may vary and is not necessarily limited thereto.

The contact holes OP-C may overlap the end portion DL-E on a plane. The contact holes OP-C may be disposed to be spaced apart from each other in the first direction DR1. The contact holes OP-C may be disposed to be spaced apart from the insulating layer PLM on a plane. The contact holes OP-C may be disposed to be spaced apart from an opening OP-CL2 of the second conductive layer CL2 on a plane. For example, in an embodiment the contact holes OP-C may be disposed to be spaced apart from the opening OP-CL2 of the second conductive layer CL2 in the first direction DR1. A portion of the first conductive layer CL1 may overlap the contact holes OP-C on a plane.

The second conductive layer CL2 may disposed to overlap the first conductive layer CL1. FIG. 7 illustrates the first conductive layer CL1 which is disposed in the inner side of the second conductive layer CL2 (e.g., in a plan view). For example, the first conductive layer CL1 may be disposed inside the second conductive layer CL2 in a plan view. However, embodiments of the present inventive concept are not necessarily limited thereto.

The opening OP-CL2 which exposes a portion of a top surface of the insulating layer PLM may be defined in the second conductive layer CL2. In an embodiment, the opening OP-CL2 may be provided in plurality. FIG. 7 illustrates five openings OP-CL2 defined in one second conductive layer CL2 and arranged in the first direction DR1. However, embodiments of the present inventive concept are not necessarily limited thereto and the number of the opening OP-CL2 may vary. In FIG. 7, a planar shape of each of the opening OP-CL2 is illustrated as a rectangle. However, embodiments of the present inventive concept are not necessarily limited thereto. For example, the planar shape of each of the opening OP-CL2 may be a polygon other than the rectangle or may be a circle or an oval. Alternatively, the respective planar shapes of the plurality of opening OP-CL2 may be the same as each other or may be different from each other.

The insulating layer PLM may be disposed to overlap the first conductive layer CL1 and the second conductive layer CL2 (e.g., in a plan view). The insulating layer PLM may be disposed in the inner side of the first conductive layer CL1 on a plane. For example, the insulating layer PLM may be disposed inside the first conductive layer CL1 and the second conductive layer CL2 in a plan view. In an embodiment, the insulating layer PLM may be disposed in the inner side of the second conductive layer CL2 on a plane. The opening OP-CL2 defined in the second conductive layer CL2 may be disposed to overlap the insulating layer PLM on a plane. The insulating layer PLM may be disposed to be spaced apart from the contact holes OP-C on a plane.

Referring to FIGS. 8A to 8C, the end portion DL-E may be disposed on a first insulating layer 10 (e.g., disposed directly thereon in the third direction DR3). The end portion DL-E may be disposed at the same layer as the gate G illustrated in FIG. 5. In an embodiment, the end portion DL-E may be formed through the same process as the gate G. The end portion DL-E may include the same material as the gate G.

However, the position of the end portion DL-E is not necessarily limited thereto. For example, in an embodiment the end portion DL-E may be disposed at the same layer, include the same material, and have the same stacked structure as the upper electrode UE illustrated in FIG. 5. Alternatively, some of the plurality of signal lines may be formed through the same process as the gate G (see FIG. 5), and others may be formed through the same process as the upper electrode UE (see FIG. 5).

In an embodiment, the data line DL may be disposed on one layer and have a one-body shape. However, embodiments of the present inventive concept are not necessarily limited thereto. For example, in an embodiment one data line DL may include a plurality of portions disposed on different layers. For example, the line portion DL-S may include two or more portions.

The first conductive layer CL1 may be disposed on a fourth insulating layer 40 (e.g., disposed directly thereon in the third direction DR3). The first conductive layer CL1 may be connected to the end portion DL-E through the contact hole OP-C passing through second to fourth insulating layers 20, 30 and 40. For example, the first conductive layer CL1 may be connected to the end portion DL-E through the contact hole OP-C. In an embodiment, the second to fourth insulating layers 20, 30 and 40 may be formed through the same process as the second to fourth insulating layers 20, 30 and 40 of the display area DP-DA illustrated in FIG. 5. In the present disclosure, the insulating layers disposed between the end portion DL-E and the first conductive layer CL1 (e.g., in a thickness direction of the signal pad DP-PD, such as the third direction DR3) may be defined as a pad insulating layer IL-P. In this embodiment, the second to fourth insulating layers 20, 30 and 40 may be defined as the pad insulating layer IL-P. However, the number of layers included in the pad insulating layer IL-P is not necessarily limited thereto and may vary. For example, the stacked structure of the pad insulating layer IL-P may be changed according to the stacked structure of the circuit element layer DP-CL (see FIG. 5). In an embodiment, the contact hole OP-C may be defined by insulating layers more than the number of the second to fourth insulating layers 20, 30 and 40, or may be defined by insulating layers less than the number of the second to fourth insulating layers 20, 30 and 40. The first conductive layer CL1 and the end portion DL-E may be distinguished from each other by the pad insulating layer IL-P (e.g., the second to fourth insulating layers 20, 30 and 40) disposed therebetween.

The second conductive layer CL2 may disposed on the first conductive layer CL1 (e.g., in the third direction DR3). In an embodiment, an area that does not overlap the insulating layer PLM (e.g., in the third direction DR3) of the second conductive layer CL2 may be in direct contact with the first conductive layer CL1. An area, which overlaps the insulating layer PLM (e.g., in the third direction DR3), of the second conductive layer CL2 may be in direct contact with the insulating layer PLM. In other words, the insulating layer PLM may be not disposed on a portion of the first conductive layer CL1, which is in direct contact with the second conductive layer CL2, and the insulating layer PLM may expose the portion of the first conductive layer CL1.

In an embodiment, the first conductive layer CL1 may be formed through the same process as the first connection electrode CNE1 described with reference with FIG. 5, and the second conductive layer CL2 may be formed through the same process as the second connection electrode CNE2 described with reference with FIG. 5. The first conductive layer CL1 may include the same material as the first connection electrode CNE1 (see FIG. 5), and the second conductive layer CL2 may include the same material as the second connection electrode CNE2 (see FIG. 5). As an example, FIGS. 8A to 8C each illustrate an embodiment in which the first conductive layer CL1 is disposed on (e.g., disposed directly thereon) the fourth insulating layer 40. However, embodiments of the present disclosure are not necessarily limited thereto. For example, in an embodiment the first conductive layer CL1 may be disposed on (e.g., disposed directly thereon) the third insulating layer 30, and in this embodiment, the fourth insulating layer 40 may not be disposed in the pad areas PA1 and PA2. However, embodiments of the present inventive concept are not necessarily limited thereto, and a combination of the connection electrodes formed through the same process as the first and second conductive layers CL1 and CL2 may be variously selected according to the stacked structure of the circuit element layer DP-CL (see FIG. 5) as long as the first and second conductive layers CL1 and CL2 on different layers may be provided.

In an embodiment, on a plane, the second conductive layer CL2 has a larger surface area than the first conductive layer CL1, and an edge of the second conductive layer CL2 is disposed outside an edge of the first conductive layer CL1 and covers the edge of the first conductive layer CL1. However, embodiments of the present inventive concept are not necessarily limited thereto. For example, in an embodiment the second conductive layer CL2 may have substantially the same surface area as the first conductive layer CL1, and the edge of the second conductive layer CL2 may be substantially aligned with the edge of the first conductive layer CL1.

One portion of the second conductive layer CL2 may include a portion overlapping the insulating layer PLM on a plane. The insulating layer PLM may be disposed between the first conductive layer CL1 and the second conductive layer CL2 on a cross-section. The insulating layer PLM may be disposed on the first conductive layer CL1 (e.g., disposed directly thereon in the third direction DR3), and a side surface of the insulating layer PLM may be covered by the second conductive layer CL2. For example, in an embodiment an entirety of the side surfaces of the insulating layer PLM may be covered by the second conductive layer CL2. In an embodiment, the second conductive layer CL2 may expose a portion of the top surface of the insulating layer PLM through the opening OP-CL2. The insulating layer PLM may be disposed in the inner side of the first conductive layer CL1 and the second conductive layer CL2 on a plane.

In an embodiment, each of the first conductive layer CL1 and the second conductive layer CL2 may have a multilayer structure. For example, in an embodiment each of the first conductive layer CL1 and the second conductive layer CL2 may have a three-layer structure of a first layer, a second layer, and a third layer which are stacked in sequence (e.g., in the third direction DR3). In an embodiment, the second layer may have higher conductivity than each of the first layer and the third layer. For example, in an embodiment the first layer and the third layer may be titanium (Ti), and the second layer may be aluminum (Al).

The insulating layer PLM may be disposed between the first conductive layer CL1 and the second conductive layer CL2. A bottom surface of the insulating layer PLM may be covered by the first conductive layer CL1, and the side surface of the insulating layer PLM may be covered by the second conductive layer CL2. For example, in an embodiment, an entirety of the bottom surface of the insulating layer PLM may be covered by the first conductive layer CL1. One portion of the top surface of the insulating layer PLM may be exposed by the opening OP-CL2 defined in the second conductive layer CL2, and the other portion of the top surface may be covered by the second conductive layer CL2.

In an embodiment, the insulating layer PLM may be formed through the same process as the fifth insulating layer 50 (see FIG. 5). However, embodiments of the present inventive concept are not necessarily limited thereto, and a combination of the connection electrodes formed through the same process as the first and second conductive layers CL1 and CL2 may be variously selected according to the stacked structure of the circuit element layer DP-CL (see FIG. 5). Accordingly, an insulating layer formed through the same process as the insulating layer PLM may also be variously selected.

In an embodiment, the insulating layer PLM may have a trapezoidal shape on a cross-section. However, embodiments of the present inventive concept are not necessarily limited thereto. For example, in some embodiments the insulating layer PLM may have a rectangular shape or an inverted trapezoidal shape on a cross-section.

The insulating layer PLM may include a polymer. In an embodiment, the insulating layer PLM may include a thermosetting polymer. However, embodiments of the present inventive concept are not necessarily limited thereto, and the insulating layer PLM may include a thermoplastic polymer. The insulating layer PLM may be formed from a negative photoresist material. The negative photoresist material may indicate a material in which a non-light-exposed portion dissolves in a developer. However, embodiments of the present inventive concept are not necessarily limited thereto, and the insulating layer PLM may be formed from a positive photoresist material in some embodiments. The positive photoresist material may indicate a material in which a light-exposed portion dissolves in a developer. The insulating layer PLM according to an embodiment of the present inventive concept may be disposed as one body without being patterned on one signal pad DP-PD, and thus have a degree of material freedom at which various polymer materials may be applied to the insulating layer PLM. In addition, since the insulating layer PLM according to an embodiment of the present inventive concept is disposed as one body without being patterned on one signal pad DP-PD, a contact area between the insulating layer PLM and the first conductive layer CL1 may be sufficient to have excellent bonding force, thereby preventing the insulating layer PLM from being lost on the first conductive layer CL1. However, in a comparative embodiment in which an insulating layer is micro-patterned and disposed unlike an embodiment of the present inventive concept, the micro-patterning may be impossible or difficult to perform according to the material, and even through the micro-patterning is performed, a contact area with a first conductive layer may be insufficient to have low bonding force, and thus the insulating layer may be lost during a process.

In an embodiment, the insulating layer PLM may include elastomer. The elastomer may indicate a polymer having properties of being stretched or compressed when external force is applied, and recovering its original shape when the external force is removed. In the signal pad DP-PD according to an embodiment of the present inventive concept, the insulating layer PLM including the elastomer may be disposed between the first conductive layer CL1 and the second conductive layer CL2, thereby imparting restoring force to the signal pad DP-PD after bonding. Accordingly, bonding reliability may be secured. In an embodiment, a modulus of the insulating layer PLM may be in a range of about 2 GPa to about 10 GPa. When the insulating layer PLM has the modulus in the foregoing range, bonding retention of the signal pad DP-PD may be increased.

Referring to FIGS. 8B and 8C, the second conductive layer CL2 disposed on the top surface of the insulating layer PLM may be a portion protruding the furthest in the third direction DR3 in the signal pad DP-PD. As illustrated in FIG. 9, the portion of the second conductive layer CL2 protruding the furthest in the third direction DR3 in the signal pad DP-PD may be in direct contact with a bump electrode BP of an electronic component and be electrically connected to the bump electrode BP. As the signal pad DP-PD according to an embodiment of the present inventive concept includes the patterned second conductive layer CL2, a degree of freedom for micro-patterning may be high, and also resistance stability with the bump electrode BP of the electronic component may be secured.

Referring to FIG. 9, the second conductive layer CL2 may be in direct contact with the bump electrode BP of the electronic component to be electrically connected to the bump electrode BP. For example, in an embodiment a portion, which is disposed on the top surface of the insulating layer PLM (e.g., disposed directly thereon in the third direction DR3), of the second conductive layer CL2 may be a portion, which protrudes the furthest in the third direction DR3, of the signal pad DP-PD. When the signal pad DP-PD of the display panel DP is bonded to the electronic component, the second conductive layer CL2 may come into direct contact with the bump electrode BP.

FIG. 9 illustrates only the bump electrode BP of the electronic component as a matter of convenience, and the bump electrode BP may correspond to the chip bump electrode DC-BP and the board bump electrode PB-BP in FIG. 6. In addition, an adhesive layer CF which bonds the signal pad DP-PD and the bump electrode BP to each other may correspond to the first adhesive layer CF1 and the second adhesive layer CF2 in FIG. 6, and the same contents about the first and second adhesive layers CF1 and CF2 may apply to the adhesive layer CF.

As the insulating layer PLM including the elastomer is disposed between the first conductive layer CL1 and the second conductive layer CL2, the signal pad DP-PD according to an embodiment of the present inventive concept has excellent bonding retention with the electronic component. For example, the restoring force may be imparted to the signal pad DP-PD by the elasticity of the insulating layer PLM, thereby increasing the bonding reliability between the display panel DP (see FIG. 6) and the electronic component. However, in a comparative embodiment in which a signal pad is simply made of a metal unlike the signal pad DP-PD according to an embodiment of the present inventive concept, the signal pad may not have the restoring force and thus have lower bonding retention.

In addition, the second conductive layer CL2 including a metal may be disposed on the insulating layer PLM, thereby freely performing the patterning of the second conductive layer CL2. In an embodiment, a planar shape and a contact area with the bump electrode BP of the second conductive layer CL2, which is disposed on the top surface of the insulating layer PLM, of the second conductive layer CL2, may be freely patterned through a metal mask patterning process. For example, patterning of a portion, which protrudes in the third direction DR3, of the signal pad DP-PD may be freely performed. Thus, upon bonding to the electronic component, stable resistance with the bump electrode BP may be secured through the micro-patterning of the second conductive layer CL2, thereby increasing the bonding reliability. However, in a comparative embodiment in which the protruding portion of the signal pad is patterned with a polymer material unlike the signal pad DP-PD according to an embodiment of the present inventive concept, there may be difficulty in micro-patterning, adhesion defects of the patterned polymer material, and the like.

In addition, since the insulating layer PLM including the elastomer is disposed as one body between the first conductive layer CL1 and the second conductive layer CL2 without being patterned to impart the restoring force to the signal pad DP-PD, even a polymer material which is difficult to micro-pattern in a process may apply to the insulating layer PLM. For example, the signal pad DP-PD according to an embodiment of the present inventive concept may provide the degree of material freedom at which various polymer materials may apply to the insulating layer PLM.

In addition, in the display device DD (see FIG. 6) according to an embodiment of the present inventive concept, the adhesive layer CF may not include a conductive ball, thereby preventing a short-circuit defect due to the conductive ball even though the signal pads DP-PD are densely disposed, and/or an electrical conduction defect when the conductive ball is not disposed between the signal pad DP-PD and the bump electrode BP. Accordingly, a high-resolution panel may be achieved.

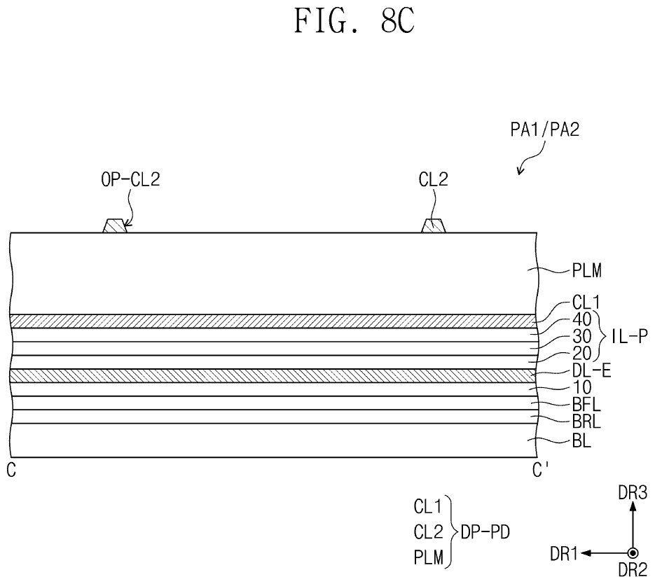

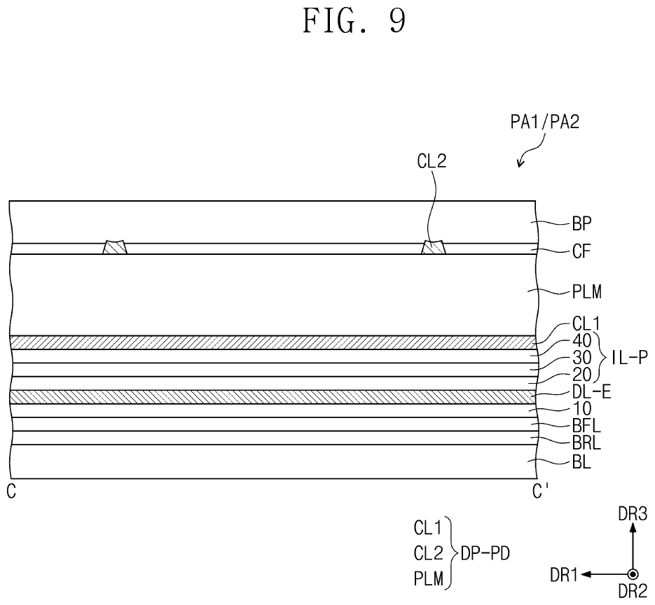

FIG. 10 is a flowchart of a method for manufacturing the display device DD (see FIG. 6) according to an embodiment of the present inventive concept. FIGS. 11 to 16 are each a cross-sectional view illustrating one step of the method for manufacturing the display device DD (see FIG. 6) according to an embodiment of the present inventive concept.

FIGS. 11 to 16 are each a cross-sectional view illustrating, as an example, a portion corresponding to line C-C′ in FIG. 7 with respect to the one step of the method for manufacturing the display device DD (see FIG. 6) according to an embodiment of the present inventive concept. The same contents described above with reference to FIGS. 6 to 9 may apply to FIGS. 10 to 16.

Referring to FIG. 10, the method for manufacturing the display device DD (see FIG. 6) according to an embodiment of the present inventive concept includes preparing a preliminary display panel in block S100, forming a display panel in block S200, and boding the display panel and an electronic component to each other in block S300.

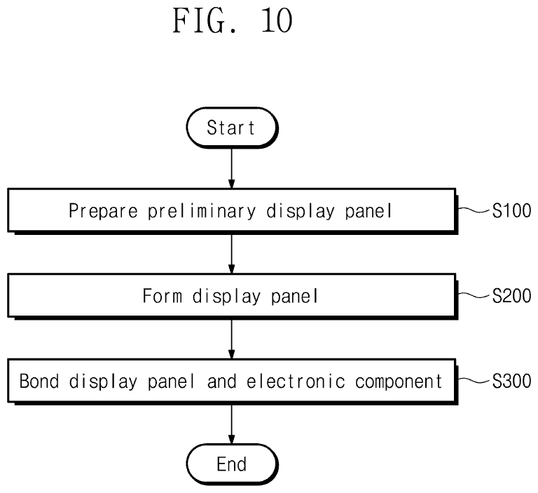

FIGS. 11 and 12 are each a cross-sectional view illustrating one step of the preparing of the preliminary display panel in block S100.

Referring to FIG. 11, an insulating layer PLM may be formed as one body on a first conductive layer CL1 without being patterned. In an embodiment, the insulating layer PLM which is not patterned and has a one-body shape may be formed on one first conductive layer CL1 (e.g., formed directly thereon in the third direction DR3). For the planar shape and arrangement of the insulating layer PLM, reference may be made to FIG. 7. In an embodiment, the insulating layer PLM may be formed by coating, exposure, and curing a photocurable organic material on the first conductive layer CL1. However, embodiments of the present inventive concept are not necessarily limited thereto, and a thermosetting organic material may be applied in some embodiments. In addition, a negative photoresist material may be applied as a material for forming the insulating layer PLM, or a positive photoresist material may be applied as the material. The insulating layer PLM may be formed, without being micro-patterned, to have a large surface area on the one first conductive layer CL1, and thus various materials may be applied thereto. For example, even a material difficult to micro-pattern may be applied as the material for forming the insulating layer PLM.

Referring to FIG. 12, in an embodiment a preliminary display panel P-DP may include a preliminary signal pad DP-PPD. In an embodiment, the preliminary signal pad DP-PPD may include a first conductive layer CL1, an insulating layer PLM disposed on the first conductive layer CL1, and a preliminary second conductive layer P-CL2 disposed on the insulating layer PLM. The preliminary second conductive layer P-CL2 may be entirely deposited on the insulating layer PLM. For example, the preliminary second conductive layer P-CL2 may cover an entirety of the upper surface of the insulating layer PLM. The first conductive layer CL1 and the preliminary second conductive layer P-CL2 may each be formed to have a three-layer structure. For example, in an embodiment the first conductive layer CL1 and the preliminary second conductive layer P-CL2 may each be formed in a structure of titanium/aluminum/titanium.

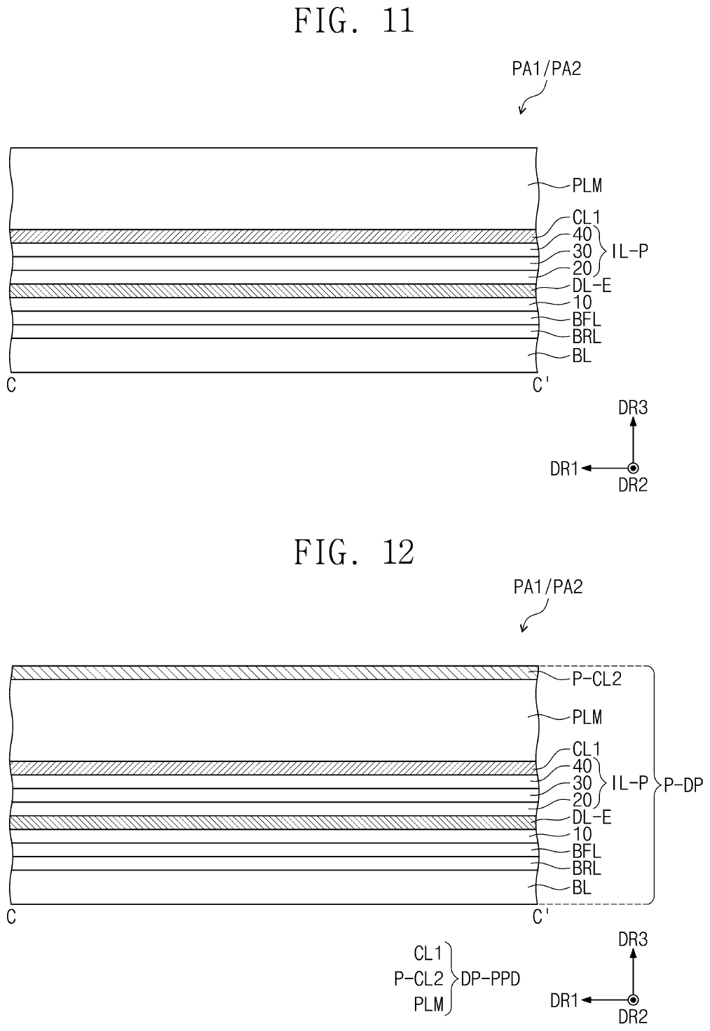

FIGS. 13 to 15 are each a cross-sectional view illustrating one step of the forming of the display panel in block S200. In an embodiment, the forming of the display panel in block S200 may include patterning the preliminary second conductive layer P-CL2 so that a portion of the top surface of the insulating layer PLM is exposed to form a second conductive layer CL2.

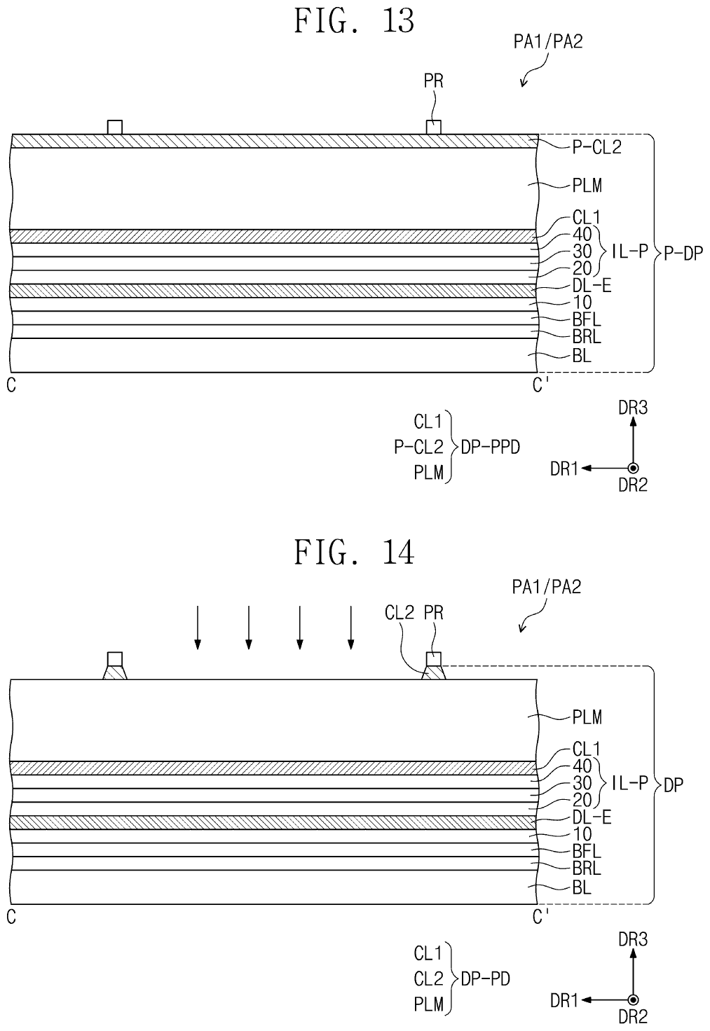

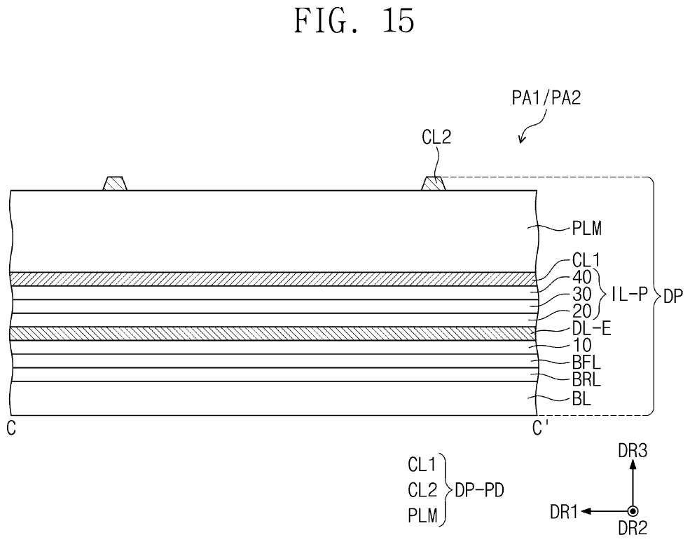

Referring to FIG. 13, in an embodiment a photoresist material PR may be patterned on the preliminary second conductive layer P-CL2 to pattern the preliminary second conductive layer P-CL2. Referring to FIG. 14, according to the patterning of the photoresist material PR, the preliminary second conductive layer P-CL2 may be patterned to form the second conductive layer CL2. In an embodiment, the preliminary second conductive layer P-CL2 may be patterned through a dry etching process using a metal mask. Referring to FIG. 15, the photoresist material PR on the second conductive layer CL2 may be removed through stripping, and a display panel DP including a signal pad DP-PD may be formed.

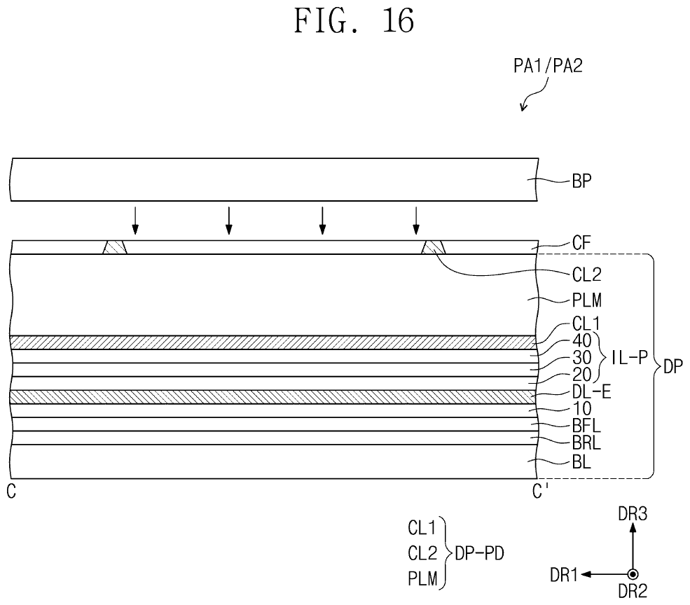

FIG. 16 is a cross-sectional view illustrating one step of the boding of the display panel and the electronic component to each other in block S300. The display panel DP and the electronic component may be bonded through an adhesive layer CF.

Referring to FIG. 16, in an embodiment the display panel DP may include the signal pad DP-PD, and the signal pad DP-PD may include the first conductive layer CL1, the insulating layer PLM disposed on the first conductive layer CL1, and the second conductive layer CL2 patterned on the insulating layer PLM. The second conductive layer CL2 patterned on the insulating layer PLM may be a portion, which protrudes the furthest in the third direction DR3, of the signal pad DP-PD. The second conductive layer CL2 patterned on the insulating layer PLM may be in direct contact with a bump electrode BP after the bonding and be electrically connected to the bump electrode BP.

In a method for manufacturing an electronic apparatus according to an embodiment of the present inventive concept, an insulating layer including a polymer may not be patterned, thereby securing a degree of freedom for a material applied to the insulating layer and having excellent bonding force to a conductive layer disposed below the insulating layer. In addition, a conductive layer disposed on the insulating layer and including a metal may be patterned, thereby easily performing a micro-patterning process on a portion for contact with a bump electrode and securing a degree of freedom for a micro-patterned shape. Accordingly, bonding processibility of the electronic apparatus may be increased.

As described above, the display panel and the electronic apparatus including the same according to an embodiment of the present inventive concept may include the insulating layer between the conductive layers included in the signal pad, thereby increasing the bonding retention between the display panel and the electronic component. In addition, the micro-patterned conductive layer may be disposed on the insulating layer of the signal pad, thereby securing the stable resistance between the signal pad and the bump electrode. Accordingly, the bonding reliability of the electronic apparatus may be increased.

In the method for manufacturing the electronic apparatus according to an embodiment of the present inventive concept, the insulating layer including the polymer may not be patterned, thereby securing the degree of freedom for the material applied to the insulating layer and having the excellent bonding force with the conductive layer disposed below the insulating layer. In addition, the conductive layer disposed on the insulating layer and including the metal may be patterned, thereby easily performing the micro-patterning process on the portion for contact with the bump electrode and securing the degree of freedom for the micro-patterned shape.

Although embodiments of the present inventive concept have been described, it is understood that the present inventive concept should not be limited to these embodiments but various changes and modifications can be made by one ordinary skilled in the art within the spirit and scope of the present inventive concept. Therefore, the technical scope of embodiments of the present inventive concept is not limited to embodiments described in the detailed description of the specification.

What is claimed is:

1. A display panel comprising:
a pixel;
a signal line electrically connected to the pixel; and
a signal pad connected to the signal line,
wherein the signal pad comprises:
a first conductive layer electrically connected to a portion of the signal line;
a second conductive layer disposed on the first conductive layer; and
an insulating layer disposed between the first conductive layer and the second conductive layer,
wherein an opening is defined in the second conductive layer, the opening exposing a portion of a top surface of the insulating layer.

2. The display panel of claim 1, wherein the insulating layer comprises elastomer.

3. The display panel of claim 1, wherein a modulus of the insulating layer is in a range of about 2 GPa to about 10 GPa.

4. The display panel of claim 1, wherein, on a plane, the insulating layer is disposed inside the first conductive layer and inside the second conductive layer.

5. The display panel of claim 1, wherein:
on a plane, the first conductive layer and the second conductive layer overlap each other; and
the second conductive layer is directly disposed on a portion of the first conductive layer, wherein the insulating layer is not disposed on the portion of the first conductive layer and the insulating layer exposes the portion of the first conductive layer.

6. The display panel of claim 1, wherein a side surface of the insulating layer is covered by the second conductive layer.

7. The display panel of claim 1, wherein a bottom surface of the insulating layer is covered by the first conductive layer.

8. The display panel of claim 1, wherein:
the portion of the signal line is disposed below the first conductive layer; and
the display panel further comprises a pad insulating layer disposed between the portion of the signal line and the first conductive layer in a thickness direction of the signal pad.

9. The display panel of claim 8, further comprising a base layer disposed below the portion of the signal line.

10. The display panel of claim 8, wherein a contact hole is defined in the pad insulating layer, the contact hole exposing the portion of the signal line; and
the first conductive layer is electrically connected to the portion of the signal line through the contact hole.

11. The display panel of claim 10, wherein the contact hole and the insulating layer are disposed to be spaced apart from each other on a plane.

12. The display panel of claim 1, wherein the opening includes a plurality of openings.

13. The display panel of claim 1, wherein each of the first conductive layer and the second conductive layer has a three-layer structure of titanium/aluminum/titanium.

14. An electronic apparatus comprising:
a display module comprising a display panel having a display area that includes a pixel, and a pad area including a signal pad connected to the pixel through a signal line, and an input sensor disposed on the display panel;
an electronic component comprising a bump electrode that is disposed on the pad area; and
an adhesive layer disposed between the display panel and the electronic component,
wherein the signal pad comprises:
a first conductive layer electrically connected to a portion of the signal line;
a second conductive layer disposed on the first conductive layer; and
an insulating layer disposed between the first conductive layer and the second conductive layer,
wherein an opening is defined in the second conductive layer, the opening exposing a portion of a top surface of the insulating layer,
wherein the second conductive layer is in direct contact with, and is electrically connected to, the bump electrode.

15. The electronic apparatus of claim 14, wherein:
on a plane, the insulating layer is disposed inside the first conductive layer and inside the second conductive layer; and
a side surface of the insulating layer is covered by the second conductive layer.

16. The electronic apparatus of claim 14, wherein:
the insulating layer comprises elastomer; and
each of the first conductive layer and the second conductive layer has a three-layer structure of titanium/aluminum/titanium.

17. The electronic apparatus of claim 14, wherein the opening includes a plurality of openings.

18. A method for manufacturing an electronic apparatus, the method comprising:
preparing a preliminary display panel comprising a preliminary signal pad including a first conductive layer, an insulating layer disposed on the first conductive layer, and a preliminary second conductive layer disposed on the insulating layer;
forming a display panel by patterning the preliminary second conductive layer to expose a portion of a top surface of the insulating layer, the patterned preliminary second conductive layer forming a second conductive layer; and
bonding the display panel and an electronic component comprising a bump electrode to each other through an adhesive layer,
wherein the bonding of the electronic component comprises bonding the second conductive layer and the bump electrode to be in direct contact with, and electrically connected to, each other.

19. The method of claim 18, wherein:
on a plane, the insulating layer is disposed inside the first conductive layer and inside the second conductive layer; and
a side surface of the insulating layer is covered by the second conductive layer.

20. The method of claim 18, wherein:
the insulating layer comprises elastomer; and
each of the first conductive layer and the second conductive layer has a three-layer structure of titanium/aluminum/titanium.
